(19) United States
(12) Patent Application Publication
(10) Pub. No.: US 2007/0221369 A1
(43) Pub. Date: Sep. 27, 2007

(54) Composite Heat Sink With Metal Base And Graphite Fins

(75) Inventors: George Getz JR., Parma Heights, OH (US); Michael Frastaci, Parma, OH (US)

Correspondence Address: WADDEY & PATTERSON, P.C., 1600 DIVISION STREET, SUITE 500, NASHVILLE, TN, 37203, US

(73) Assignee: ADVANCED ENERGY TECHNOLOGY INC., Lakewood, OH (US)

(21) Appl. No.: 11/568,472

(22) PCT Filed: Apr. 1, 2005
(86) PCT No.: PCT/US05/11175

§ 371 Date: Oct. 30, 2006

(30) Foreign Application Priority Data
Sep. 7, 2004 (US) 10/833928

(51) Int. Cl. F28F 7/00; H05K 7/20

(52) U.S. Cl. 165/185; 361/702

(57) ABSTRACT

A composite heat sink apparatus includes a metal base which has a thermal conductivity of at least about 150 W/m°K. The metal base is preferably constructed either of copper of aluminum. The heat sink apparatus further includes a plurality of fins attached to the base, the fins being constructed of anisotropic graphite material having a direction of relatively high thermal conductivity perpendicular to the base.

### TECHNICAL FIELD

The present invention relates to a heat sink capable of managing the heat from a heat source such as an electronic device.

### BACKGROUND ART

With the development of more and more sophisticated electronic devices, including those capable of increasing processing speeds and higher frequencies, having smaller size and more complicated power requirements, and exhibiting other technological advances, such as microprocessors and integrated circuits in electronic and electrical components and systems as well as in other devices such as high power optical devices, relatively extreme temperatures can be generated. However, microprocessors, integrated circuits and other sophisticated electronic components typically operate efficiently only under a certain range of threshold temperatures. The excessive heat generated during operation of these components can not only harm their own performance, but can also degrade the performance and reliability of the overall system and can even cause system failure. The increasingly wide range of environmental conditions, including temperature extremes, in which electronic systems are expected to operate, exacerbates the negative effects of excessive heat.

With the increased need for heat dissipation from microelectronic devices, thermal management becomes an increasingly important element of the design of electronic products. Both performance reliability and life expectancy of electronic equipment are inversely related to the component temperature of the equipment. For instance, a reduction in the operating temperature of a device such as a typical silicon semiconductor can correspond to an increase in the processing speed, reliability and life expectancy of the device. Therefore, to maximize the life-span and reliability of a component, controlling the device operating temperature within the limits set by the designers is of paramount importance.

Several types of heat dissipating components are utilized to facilitate heat dissipation from electronic devices. The present invention is directly applicable to finned heat sinks.

These heat sinks facilitate heat dissipation from the surface of a heat source, such as a heat-generating electronic device, to a cooler environment, usually air. The heat sink seeks to increase the heat transfer efficiency between the electronic device and the ambient air primarily by increasing the surface area that is in direct contact with the air or other heat transfer media. This allows more heat to be dissipated and thus lowers the electronic device operating temperature. The primary purpose of a heat dissipating component is to help maintain the device temperature below the maximum allowable temperature specified by its designer/manufacturer.

Typically, the heat sinks are formed of a metal, especially copper or aluminum, due to the ability of metals like copper to readily absorb heat and transfer it about its entire structure. Copper heat sinks are often formed with fins or other structures to increase the surface area of the heat sink, with air being forced across or through the fins (such as by a fan) to effect heat dissipation from the electronic component, through the copper heat sink and then to the air.

The use of copper or aluminum heat dissipating elements can present a problem because of the weight of the metal, particularly when the heat transmitting area of the heat dissipating component is significantly larger than that of the electronic device. For instance, pure copper weighs 8.96 grams per cubic centimeter (g/cm³) and pure aluminum weighs 2.70 g/cm³.

For example, in many applications, several heat sinks need to be arrayed on, e.g., a circuit board to dissipate heat from a variety of components on the board. If metallic heat sinks are employed, the sheer weight of the metal on the board can increase the chances of the board cracking or of other equally undesirable effects, and increases the weight of the component itself. For portable electronic devices, any method to reduce weight while maintaining heat dissipation characteristics is especially desirable.

Another group of materials suitable for use in heat sinks are those materials generally known as graphites, but in particular graphites such as those based on natural graphites and flexible graphite as described below. These materials are anisotropic and allow the heat sink to be designed to preferentially transfer heat in selected directions. Also, the graphite materials are much lighter in weight and thus provide many advantages over copper or aluminum.

Graphites are made up of layer planes of hexagonal arrays or networks of carbon atoms. These layer planes of hexagonally arranged carbon atoms are substantially flat and are oriented or ordered so as to be substantially parallel and equidistant to one another. The substantially flat, parallel equidistant sheets or layers of carbon atoms, usually referred to as graphene layers or basal planes, are linked or bonded together and groups thereof are arranged in crystallites. Highly ordered graphites consist of crystallites of considerable size: the crystallites being highly aligned or oriented with respect to each other and having well ordered carbon layers. In other words, highly ordered graphites have a high degree of preferred crystallite orientation. It should be noted that graphites possess anisotropic structures and thus exhibit or possess many properties that are highly directional e.g. thermal and electrical conductivity and fluid diffusion.

Briefly, graphites may be characterized as laminated structures of carbon, that is, structures consisting of superposed layers or laminae of carbon atoms joined together by weak van der Waals forces. In considering the graphite structure, two axes or directions are usually noted, to wit, the “c” axis or direction and the “a” axes or directions. For simplicity, the “c” axis or direction may be considered as the direction perpendicular to the carbon layers. The “a” axes or directions may be considered as the directions parallel to the carbon layers or the directions perpendicular to the “c” direction. The graphites suitable for manufacturing flexible graphite sheets possess a very high degree of orientation.

As noted above, the bonding forces holding the parallel layers of carbon atoms together are only weak van der Waals forces. Natural graphites can be treated so that the spacing between the superposed carbon layers or laminae can be appreciably opened up so as to provide a marked expansion in the direction perpendicular to the layers, that is, in the “c” direction, and thus form an expanded or intumesced graphite structure in which the laminar character of the carbon layers is substantially retained.

Graphite flake which has been greatly expanded and more particularly expanded so as to have a final thickness or “c” direction dimension which is as much as about 80 or more times the original “c” direction dimension can be formed without the use of a binder into cohesive or integrated sheets of expanded graphite, e.g. webs, papers, strips, tapes, foils, mats or the like (typically referred to as “flexible graphite”). The formation of graphite particles which have been expanded to have a final thickness or “c” dimension which is as much as about 80 times or more the original “c” direction dimension into integrated flexible sheets by compression, without the use of any binding material, is believed to be possible due to the mechanical interlocking, or cohesion, which is achieved between the voluminously expanded graphite particles.

In addition to flexibility, the sheet material, as noted above, has also been found to possess a high degree of anisotropy with respect to thermal and electrical conductivity and fluid diffusion, comparable to the natural graphite starting material due to orientation of the expanded graphite particles and graphite layers substantially parallel to the opposed faces of the sheet resulting from very high compression, e.g. roll pressing. Sheet material thus produced has excellent flexibility, good strength and a very high degree of orientation.

Briefly, the process of producing flexible, binderless anisotropic graphite sheet material, e.g. web, paper, strip, tape, foil, mat, or the like, comprises compressing or compacting under a predetermined load and in the absence of a binder, expanded graphite particles which have a “c” direction dimension which is as much as about 80 or more times that of the original particles so as to form a substantially flat, flexible, integrated graphite sheet. The expanded graphite particles that generally are worm-like or vermiform in appearance, once compressed, will maintain the compression set and alignment with the opposed major surfaces of the sheet. The density and thickness of the sheet material can be varied by controlling the degree of compression. The density of the sheet material can be within the range of from about 0.04 g/cm³ to about 2.0 g/cm³. The flexible graphite sheet material exhibits an appreciable degree of anisotropy due to the alignment of graphite particles parallel to the major opposed, parallel surfaces of the sheet, with the degree of anisotropy increasing upon roll pressing of the sheet material to increase orientation. In roll pressed anisotropic sheet material, the thickness, i.e. the direction perpendicular to the opposed, parallel sheet surfaces comprises the “c” direction and the directions ranging along the length and width, i.e. along or parallel to the opposed, major surfaces comprises the “a” directions and the thermal, electrical and fluid diffusion properties of the sheet are very different, by orders of magnitude, for the “c” and “a” directions.

There is a continuing need for improved heat sink designs which provide relatively high thermal conductivity and relatively low weight as compared to prior designs.

### DISCLOSURE OF THE INVENTION

The present invention provides a heat sink apparatus which comprises a metallic base having a thermal conductivity of at least about 150 W/m°K, and a plurality of fins attached to the base, the fins being constructed of anisotropic graphite material having a direction of relatively high thermal conductivity perpendicular to the base.

In specific embodiments of the invention the base may be constructed either of copper or aluminum.

Accordingly, it is an object of the present invention to provide an improved heat sink design for thermal management of electronic devices.

Still another object of the present invention is the provision of a composite heat sink design having a metal base and having fins constructed of anisotropic graphite material.

And another object of the present invention is the provision of a composite heat sink having a copper base with graphite fins, which provides a thermal performance approximately equal to that of an all copper heat sink while having a weight less than that of the all copper heat sink.

And another object of the present invention is the provision of a heat sink apparatus having an aluminum base and a plurality of graphite fins, so that the heat sink apparatus has a thermal performance greater than that of a similar sized all aluminum heat sink while having a weight no greater than that of the all aluminum heat sink.

Other and further objects, features, and advantages of the present invention will be readily apparent to those skilled in the art, upon a reading of the following disclosure when taken in conjunction with the accompanying drawings.

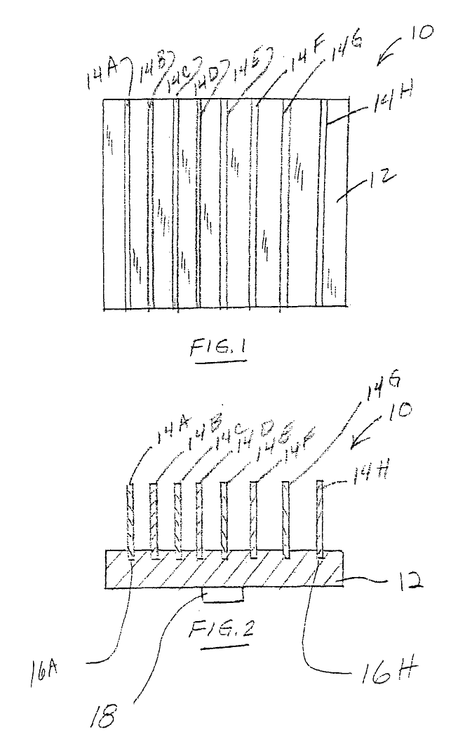

FIG. 1 is a top plan view of a heat sink constructed in accordance with the present invention.

FIG. 2 is a side plan view of the heat sink of FIG. 1.

### BEST MODE FOR CARRYING OUT THE INVENTION

As noted, one material from which the heat sinks of the present invention may be constructed is graphite sheet material. Before describing the construction of the heat sinks, a brief description of graphite and its formation into flexible sheets is in order.

### Preparation of Flexible Graphite Sheet

Graphite is a crystalline form of carbon comprising atoms covalently bonded in flat layered planes with weaker bonds between the planes. By treating particles of graphite, such as natural graphite flake, with an intercalant of, e.g. a solution of sulfuric and nitric acid, the crystal structure of the graphite reacts to form a compound of graphite and the intercalant. The treated particles of graphite are hereafter referred to as “particles of intercalated graphite.” Upon exposure to high temperature, the intercalant within the graphite decomposes and volatilizes, causing the particles of intercalated graphite to expand in dimension as much as about 80 or more times its original volume in an accordion-like fashion in the “c” direction, i.e. in the direction perpendicular to the crystalline planes of the graphite. The exfoliated graphite particles are vermiform in appearance, and are therefore commonly referred to as worms. The worms may be compressed together into flexible sheets that, unlike the original graphite flakes, can be formed and cut into various shapes.

Graphite starting materials suitable for use in the present invention include highly graphitic carbonaceous materials capable of intercalating organic and inorganic acids as well as halogens and then expanding when exposed to heat. These highly graphitic carbonaceous materials most preferably have a degree of graphitization of about 1.0. As used in this disclosure, the term “degree of graphitization” refers to the value g according to the formula:

$$g = \frac{3.45 - d ( 002 )}{0.095}$$

where d(002) is the spacing between the graphitic layers of the carbons in the crystal structure measured in Angstrom units. The spacing d between graphite layers is measured by standard X-ray diffraction techniques. The positions of diffraction peaks corresponding to the (002), (004) and (006) Miller Indices are measured, and standard least-squares techniques are employed to derive spacing which minimizes the total error for all of these peaks. Examples of highly graphitic carbonaceous materials include natural graphites from various sources, as well as other carbonaceous materials such as graphite prepared by chemical vapor deposition, high temperature pyrolysis of polymers, or crystallization from molten metal solutions and the like. Natural graphite is most preferred.

The graphite starting materials used in the present invention may contain non-graphite components so long as the crystal structure of the starting materials maintains the required degree of graphitization and they are capable of exfoliation. Generally, any carbon-containing material, the crystal structure of which possesses the required degree of graphitization and which can be exfoliated, is suitable for use with the present invention. Such graphite preferably has a purity of at least about eighty weight percent. More preferably, the graphite employed for the present invention will have a purity of at least about 94%. In the most preferred embodiment, the graphite employed will have a purity of at least about 98%.

A common method for manufacturing graphite sheet is described by Shane et al. in U.S. Pat. No. 3,404,061, the disclosure of which is incorporated herein by reference. In the typical practice of the Shane et al. method, natural graphite flakes are intercalated by dispersing the flakes in a solution containing e.g., a mixture of nitric and sulfuric acid, advantageously at a level of about 20 to about 300 parts by weight of intercalant solution per 100 parts by weight of graphite flakes (pph). The intercalation solution contains oxidizing and other intercalating agents known in the art. Examples include those containing oxidizing agents and oxidizing mixtures, such as solutions containing nitric acid, potassium chlorate, chromic acid, potassium permanganate, potassium chromate, potassium dichromate, perchloric acid, and the like, or mixtures, such as for example, concentrated nitric acid and chlorate, chromic acid and phosphoric acid, sulfuric acid and nitric acid, or mixtures of a strong organic acid, e.g. trifluoroacetic acid, and a strong oxidizing agent soluble in the organic acid. Alternatively, an electric potential can be used to bring about oxidation of the graphite. Chemical species that can be introduced into the graphite crystal using electrolytic oxidation include sulfuric acid as well as other acids.

In a preferred embodiment, the intercalating agent is a solution of a mixture of sulfuric acid, or sulfuric acid and phosphoric acid, and an oxidizing agent, i.e. nitric acid, perchloric acid, chromic acid, potassium permanganate, hydrogen peroxide, iodic or periodic acids, or the like. Although less preferred, the intercalation solution may contain metal halides such as ferric chloride, and ferric chloride mixed with sulfuric acid, or a halide, such as bromine as a solution of bromine and sulfuric acid or bromine in an organic solvent.

The quantity of intercalation solution may range from about 20 to about 350 pph and more typically about 40 to about 160 pph. After the flakes are intercalated, any excess solution is drained from the flakes and the flakes are water-washed. Alternatively, the quantity of the intercalation solution may be limited to between about 10 and about 40 pph, which permits the washing step to be eliminated as taught and described in U.S. Pat. No. 4,895,713, the disclosure of which is also herein incorporated by reference.

The particles of graphite flake treated with intercalation solution can optionally be contacted, e.g. by blending, with a reducing organic agent selected from alcohols, sugars, aldehydes and esters which are reactive with the surface film of oxidizing intercalating solution at temperatures in the range of 25° C. and 125° C. Suitable specific organic agents include hexadecanol, octadecanol, 1-octanol, 2-octanol, decylalcohol, 1, 10 decanediol, decylaldehyde, 1-propanol, 1,3 propanediol, ethyleneglycol, polypropylene glycol, dextrose, fructose, lactose, sucrose, potato starch, ethylene glycol monostearate, diethylene glycol dibenzoate, propylene glycol monostearate, glycerol monostearate, dimethyl oxylate, diethyl oxylate, methyl formate, ethyl formate, ascorbic acid and lignin-derived compounds, such as sodium lignosulfate. The amount of organic reducing agent is suitably from about 0.5 to 4% by weight of the particles of graphite flake.

The use of an expansion aid applied prior to, during or immediately after intercalation can also provide improvements. Among these improvements can be reduced exfoliation temperature and increased expanded volume (also referred to as “worm volume”). An expansion aid in this context will advantageously be an organic material sufficiently soluble in the intercalation solution to achieve an improvement in expansion. More narrowly, organic materials of this type that contain carbon, hydrogen and oxygen, preferably exclusively, may be employed. Carboxylic acids have been found especially effective. A suitable carboxylic acid useful as the expansion aid can be selected from aromatic, aliphatic or cycloaliphatic, straight chain or branched chain, saturated and unsaturated monocarboxylic acids, dicarboxylic acids and polycarboxylic acids which have at least 1 carbon atom, and preferably up to about 15 carbon atoms, which is soluble in the intercalation solution in amounts effective to provide a measurable improvement of one or more aspects of exfoliation. Suitable organic solvents can be employed to improve solubility of an organic expansion aid in the intercalation solution.

Representative examples of saturated aliphatic carboxylic acids are acids such as those of the formula H(CH₂)ₙCOOH wherein n is a number of from 0 to about 5, including formic, acetic, propionic, butyric, pentanoic, hexanoic, and the like. In place of the carboxylic acids, the anhydrides or reactive carboxylic acid derivatives such as alkyl esters can also be employed. Representative of alkyl esters are methyl formate and ethyl formate. Sulfuric acid, nitric acid and other known aqueous intercalants have the ability to decompose formic acid, ultimately to water and carbon dioxide. Because of this, formic acid and other sensitive expansion aids are advantageously contacted with the graphite flake prior to immersion of the flake in aqueous intercalant. Representative of dicarboxylic acids are aliphatic dicarboxylic acids having 2-12 carbon atoms, in particular oxalic acid, fumaric acid, malonic acid, maleic acid, succinic acid, glutaric acid, adipic acid, 1,5-pentanedicarboxylic acid, 1,6-hexanedicarboxylic acid, 1,10-decanedicarboxylic acid, cyclohexane-1,4-dicarboxylic acid and aromatic dicarboxylic acids such as phthalic acid or terephthalic acid. Representative of alkyl esters are dimethyl oxylate and diethyl oxylate. Representative of cycloaliphatic acids is cyclohexane carboxylic acid and of aromatic carboxylic acids are benzoic acid, naphthoic acid, anthranilic acid, p-aminobenzoic acid, salicylic acid, o-, m- and p-tolyl acids, methoxy and ethoxybenzoic acids, acetoacetamidobenzoic acids and, acetamidobenzoic acids, phenylacetic acid and naphthoic acids. Representative of hydroxy aromatic acids are hydroxybenzoic acid, 3-hydroxy-1-naphthoic acid, 3-hydroxy-2-naphthoic acid, 4-hydroxy-2-naphthoic acid, 5-hydroxy-1-naphthoic acid, 5-hydroxy-2-naphthoic acid, 6-hydroxy-2-naphthoic acid and 7-hydroxy-2-naphthoic acid. Prominent among the polycarboxylic acids is citric acid.

The intercalation solution will be aqueous and will preferably contain an amount of expansion aid of from about 1 to 10%, the amount being effective to enhance exfoliation. In the embodiment wherein the expansion aid is contacted with the graphite flake prior to or after immersing in the aqueous intercalation solution, the expansion aid can be admixed with the graphite by suitable means, such as a V-blender, typically in an amount of from about 0.2% to about 10% by weight of the graphite flake.

After intercalating the graphite flake, and following the blending of the intercalant coated intercalated graphite flake with the organic reducing agent, the blend is exposed to temperatures in the range of 25° to 125° C. to promote reaction of the reducing agent and intercalant coating. The heating period is up to about 20 hours, with shorter heating periods, e.g., at least about 10 minutes, for higher temperatures in the above-noted range. Times of one half hour or less, e.g., on the order of 10 to 25 minutes, can be employed at the higher temperatures.

The above described methods for intercalating and exfoliating graphite flake may beneficially be augmented by a pretreatment of the graphite flake at graphitization temperatures, i.e. temperatures in the range of about 3000° C. and above and by the inclusion in the intercalant of a lubricious additive.

The pretreatment, or annealing, of the graphite flake results in significantly increased expansion (i.e., increase in expansion volume of up to 300% or greater) when the flake is subsequently subjected to intercalation and exfoliation. Indeed, desirably, the increase in expansion is at least about 50%, as compared to similar processing without the annealing step. The temperatures employed for the annealing step should not be significantly below 3000° C., because temperatures even 100° C. lower result in substantially reduced expansion.

The annealing of the present invention is performed for a period of time sufficient to result in a flake having an enhanced degree of expansion upon intercalation and subsequent exfoliation. Typically the time required will be 1 hour or more, preferably 1 to 3 hours and will most advantageously proceed in an inert environment. For maximum beneficial results, the annealed graphite flake will also be subjected to other processes known in the art to enhance the degree expansion—namely intercalation in the presence of an organic reducing agent, an intercalation aid such as an organic acid, and a surfactant wash following intercalation. Moreover, for maximum beneficial results, the intercalation step may be repeated.

The annealing step of the instant invention may be performed in an induction furnace or other such apparatus as is known and appreciated in the art of graphitization; for the temperatures here employed, which are in the range of 3000° C., are at the high end of the range encountered in graphitization processes.

Because it has been observed that the worms produced using graphite subjected to pre-intercalation annealing can sometimes “clump” together, which can negatively impact area weight uniformity, an additive that assists in the formation of “free flowing” worms is highly desirable. The addition of a lubricious additive to the intercalation solution facilitates the more uniform distribution of the worms across the bed of a compression apparatus (such as the bed of a calender station conventionally used for compressing, or “calendering,” graphite worms into an integrated graphite article). The resulting article therefore has higher area weight uniformity and greater tensile strength. The lubricious additive is preferably a long chain hydrocarbon, more preferably a hydrocarbon having at least about 10 carbons. Other organic compounds having long chain hydrocarbon groups, even if other functional groups are present, can also be employed.

More preferably, the lubricious additive is an oil, with a mineral oil being most preferred, especially considering the fact that mineral oils are less prone to rancidity and odors, which can be an important consideration for long term storage. It will be noted that certain of the expansion aids detailed above also meet the definition of a lubricious additive. When these materials are used as the expansion aid, it may not be necessary to include a separate lubricious additive in the intercalant.

The lubricious additive is present in the intercalant in an amount of at least about 1.4 pph, more preferably at least about 1.8 pph. Although the upper limit of the inclusion of lubricous additive is not as critical as the lower limit, there does not appear to be any significant additional advantage to including the lubricious additive at a level of greater than about 4 pph.

The thus treated particles of graphite are sometimes referred to as “particles of intercalated graphite.” Upon exposure to high temperature, e.g. temperatures of at least about 160° C. and especially about 700° C. to 1000° C. and higher, the particles of intercalated graphite expand as much as about 80 to 1000 or more times their original volume in an accordion-like fashion in the c-direction, i.e. in the direction perpendicular to the crystalline planes of the constituent graphite particles. The expanded, i.e. exfoliated, graphite particles are vermiform in appearance, and are therefore commonly referred to as worms. The worms may be compressed together into flexible sheets that, unlike the original graphite flakes, can be formed and cut into various shapes.

Flexible graphite sheet and foil are coherent, with good handling strength, and are suitably compressed, e.g. by roll pressing, to a thickness of about 0.075 mm to 3.75 mm and a typical density of about 0.1 to 1.5 grams per cubic centimeter (g/cm³). From about 1.5-30% by weight of ceramic additives can be blended with the intercalated graphite flakes as described in U.S. Pat. No. 5,902,762 (which is incorporated herein by reference) to provide enhanced resin impregnation in the final flexible graphite product. The additives include ceramic fiber particles having a length of about 0.15 to 1.5 millimeters. The width of the particles is suitably from about 0.04 to 0.004 mm. The ceramic fiber particles are non-reactive and non-adhering to graphite and are stable at temperatures up to about 1100° C., preferably about 1400° C. or higher. Suitable ceramic fiber particles are formed of macerated quartz glass fibers, carbon and graphite fibers, zirconia, boron nitride, silicon carbide and magnesia fibers, naturally occurring mineral fibers such as calcium metasilicate fibers, calcium aluminum silicate fibers, aluminum oxide fibers and the like.

The flexible graphite sheet can also, at times, be advantageously treated with resin and the absorbed resin, after curing, enhances the moisture resistance and handling strength, i.e. stiffness, of the flexible graphite sheet as well as “fixing” the morphology of the sheet. Suitable resin content is preferably less than about 60% by weight, more preferably less than about 35% by weight, and most preferably from about 4% to about 15% by weight. Resins found especially useful in the practice of the present invention include acrylic-, epoxy- and phenolic-based resin systems, or mixtures thereof. Suitable epoxy resin systems include those based on diglycidyl ether or bisphenol A (DGEBA) and other multifunctional resin systems; phenolic resins that can be employed include resole and novolac phenolics.

Alternatively, the flexible graphite of the present invention may utilize particles of reground flexible graphite materials rather than freshly expanded worms. The reground materials may be newly formed material, recycled material, scrap material, or any other suitable source.

Also the processes of the present invention may use a blend of virgin materials and recycled materials.

The source material for recycled materials may be articles or trimmed portions of articles that have been compression molded as described above, or sheets that have been compressed with, for example, pre-calendering rolls, but have not yet been impregnated with resin. Furthermore, the source material may be impregnated with resin, but not yet cured, or impregnated with resin and cured. The source material may also be recycled flexible graphite fuel cell components such as flow field plates or electrodes. Each of the various sources of graphite may be used as is or blended with natural graphite flakes.

Once the source material of flexible graphite is available, it can then be comminuted by known processes or devices, such as a jet mill, air mill, blender, etc. to produce particles. Preferably, a majority of the particles have a diameter such that they will pass through 20 U.S. mesh; more preferably a major portion (greater than about 20%, most preferably greater than about 50%) will not pass through 80 U.S. mesh. Most preferably the particles have a particle size of no greater than about 20 mesh. It may be desirable to cool the flexible graphite when it is resin-impregnated as it is being comminuted to avoid heat damage to the resin system during the comminution process.

The size of the comminuted particles may be chosen so as to balance machinability and formability of the graphite article with the thermal characteristics desired. Thus, smaller particles will result in a graphite article which is easier to machine and/or form, whereas larger particles will result in a graphite article having higher anisotropy, and, therefore, greater in-plane electrical and thermal conductivity.

Once the source material is comminuted (if the source material has been resin impregnated, then preferably the resin is removed from the particles), it is then re-expanded. The re-expansion may occur by using the intercalation and exfoliation process described above and those described in U.S. Pat. No. 3,404,061 to Shane et al. and U.S. Pat. No. 4,895,713 to Greinke et al.

Typically, after intercalation the particles are exfoliated by heating the intercalated particles in a furnace. During this exfoliation step, intercalated natural graphite flakes may be added to the recycled intercalated particles. Preferably, during the re-expansion step the particles are expanded to have a specific volume in the range of at least about 100 cc/g and up to about 350 cc/g or greater. Finally, after the re-expansion step, the re-expanded particles may be compressed into coherent materials and impregnated with resin, as described.

Graphite materials prepared according to the foregoing description can also be generally referred to as compressed particles of exfoliated graphite. Since the materials are resin-impregnated, the resin in the sheets needs to be cured before the sheets are used in their intended applications, such as for electronic thermal management.

### Preparation of Preferred Graphite Materials

The graphite fins of the heat sinks described below are preferably constructed from a resin impregnated graphite material in the manner set forth in the U.S. Patent Application filed Apr. 23, 2004 of Norley et al. entitled “RESIN-IMPREGNATED FLEXIBLE GRAPHITE SHEETS”, assigned to the assignee of the present invention, having docket number P1048-1/N11169 the details of which are incorporated herein by reference.

According to the Norley et al. process, flexible graphite sheets prepared as described above and having a thickness of about 4 mm to 7 mm, or higher, are impregnated with a thermosetting resin such as an epoxy, acrylic or phenolic resin system. Suitable epoxy resins include diglycidyl ether of bisphenol A (DGEBA) resin systems; other multifunctional epoxy resins systems are also suitable for use in the present invention. Suitable phenolic resin systems include those containing resole and novolac resins. The sheets are then calendered to a thickness of up to about 3 mm, more preferably about 0.35 mm to 0.5 mm, at which time the calendered, epoxy impregnated flexible sheets have a density of about 1.4 g/cm³ to about 1.9 g/cm³.

The amount of resin within the epoxy impregnated graphite sheets should be an amount sufficient to ensure that the final assembled and cured layered structure is dense and cohesive, yet the anisotropic thermal conductivity associated with a densified graphite structure has not been adversely impacted. Suitable resin content is preferably at least about 3% by weight, more preferably from about 5% to about 45% by weight depending on the characteristics desired in the final product.

In a typical resin impregnation step, the flexible graphite sheet is passed through a vessel and impregnated with the resin system from, e.g. spray nozzles, the resin system advantageously being “pulled through the mat” by means of a vacuum chamber. Typically, but not necessarily, the resin system is solvated to facilitate application into the flexible graphite sheet. The resin is thereafter preferably dried, reducing the tack of the resin and the resin-impregnated sheet.

One type of apparatus for continuously forming resin-impregnated and calendered flexible graphite sheet is shown in U.S. Pat. No. 6,432,336, the disclosure of which is incorporated herein by reference.

Following the compression step (such as by calendering), the impregnated materials are cut to suitable-sized pieces and placed in a press, where the resin is cured at an elevated temperature. The temperature should be sufficient to ensure that the lamellar structure is densified at the curing pressure, while the thermal properties of the structure are not adversely impacted. Generally, this will require a temperature of at least about 90° C., and generally up to about 200° C. Most preferably, cure is at a temperature of from about 150° C. to 200° C. The pressure employed for curing will be somewhat a function of the temperature utilized, but will be sufficient to ensure that the lamellar structure is densified without adversely impacting the thermal properties of the structure. Generally, for convenience of manufacture, the minimum required pressure to densify the structure to the required degree will be utilized. Such a pressure will generally be at least about 7 megapascals (Mpa, equivalent to about 1000 pounds per square inch), and need not be more than about 35 Mpa (equivalent to about 5000 psi), and more commonly from about 7 to about 21 Mpa (1000 to 3000 psi). The curing time may vary depending on the resin system and the temperature and pressure employed, but generally will range from about 0.5 hours to 2 hours. After curing is complete, the composites are seen to have a density of at least about 1.8 g/cm³ and commonly from about 1.8 g/cm³ to 2.0 g/cm³.

Although the formation of sheets through calendering or molding is the most common method of formation of the graphite materials useful in the practice of the present invention, other forming methods can also be employed. For instance, the exfoliated graphite particles can be compression molded into a net shape or near net shape. Thus, if the end application requires an article, such as a heat sink or heat spreader, assuming a certain shape or profile, that shape or profile can be molded into the graphite article, before or after resin impregnation. Cure would then take place in a mold assuming the same shape; indeed, in the preferred embodiment, compression and curing will take place in the same mold. Machining to the final shape can then be effected.

### The Detailed Embodiment of FIGS. 1-2

Referring now to the drawings, and particularly to FIGS. 1 and 2, a heat sink apparatus is shown and generally designated by the numeral 10. The heat sink apparatus 10 includes a metal base 12 having a thermal conductivity of at least 150 W/m°K. Preferably the metal base 12 is constructed of either copper or aluminum. A copper base 12 will have a thermal conductivity of approximately 350 W/m°K or higher. An aluminum metal base 12 will have a thermal conductivity of approximately 150 W/m°K or higher.

The heat sink apparatus 10 further includes a plurality of fins such as 14A-H.

The fins 14 are constructed of flexible graphite sheet material, and preferably are constructed from a resin-impregnated flexible graphite sheets.

As previously noted, the graphite sheet material is anisotropic and has a relatively high thermal conductivity of approximately 400 W/m°K in the plane of the sheet, and has a very much lower thermal conductivity across the thickness of the sheet. Thus, the fins when constructed of the sheet material have a relatively high thermal conductivity within the plane of the fin which is generally perpendicular to the orientation of the base 12.

The graphite material from which the fins are constructed is considerably lighter than a comparable size copper fin, and is also lighter than a comparable size aluminum fin. Pure copper weighs 8.96 gm/cm³ and pure aluminum weighs 2.70 gm/cm³. The density of the graphite sheet material, on the other hand, can be within the range of from about 0.04 gm/cm³ to about 2.0 gm/cm³. The preferred resin-impregnated graphite material described above has a density of approximately 1.94 gm/cm³.

Thus when using a copper base 12, with the graphite fins 14, the heat sink apparatus 10 will have a thermal performance approximately equal to that of an all copper heat sink while having a weight less than that of the all copper heat sink.

Similarly, when utilizing an aluminum base 12 with the graphite fins 14, the heat sink apparatus 10 will have a thermal performance greater than that of a similar size all aluminum heat sink while having a weight of less than and certainly no greater than that of an all aluminum heat sink.

Preferably, the fins 14 are attached to the base 12 by machining a plurality of grooves such as 16A-H in the base 12, with the fins 14 each having their lower edges closely received within the respective groove 16.

The fins 14 may be held in place within the groove 16 by a friction fit, a thermal shrink fit, or by the use of adhesive.

An electronic device 18 which is to be cooled by the heat sink apparatus 10 is schematically illustrated in FIG. 2 and engages the lower surface of the base 12. The electronic device 18 may be thermally connected to the base 12 by a layer of thermal grease or adhesive or by a thermal interface layer constructed of a thin sheet of graphite material.

Thus it is seen that the apparatus of the present invention readily achieves the ends and advantages mentioned as well as those inherent therein. While certain preferred embodiments of the invention have been illustrated and described for purposes of the present disclosure, numerous changes in the arrangement and construction may be made by those skilled in the art, which changes are encompassed within the scope and spirit of the present invention as defined by the appended claims.

1. A heat sink apparatus, comprising:
a metal base having a thermal conductivity of at least about 150 W/m°K; and
a plurality of fins attached to the base, the fins being constructed of at least one sheet of compressed particles of exfoliated graphite.

2. The apparatus of claim 1, wherein the fins are perpendicular to the base.

3. The apparatus of claim 1, wherein the base is constructed of copper.

4. The apparatus of claim 1, wherein the base is constructed of aluminum.

5. The apparatus of claim 1, wherein:
the base has a plurality of parallel grooves formed therein; and
the fins are planar fins, each of the fins being closely received in one of the grooves.

6. The apparatus of claim 1, wherein the fins are constructed of resin impregnated flexible graphite sheets pressure cured at a temperature of at least about 90° C. and at a pressure of at least about 7 Mpa.

7. A heat sink apparatus, comprising:
a copper base; and
a plurality of planar graphite fins attached to the base, the graphite fins being formed of at least one sheet of compressed particles of exfoliated graphite having a relatively high thermal conductivity within the plane of the fin and relatively low thermal conductivity across a thickness of each fin, so that the heat sink apparatus has a thermal performance approximately equal to that of an all copper heat sink while having a weight less than that of the all copper heat sink.

8. The apparatus of claim 7, wherein the graphite fins are constructed of resin impregnated graphite sheets pressure cured at temperature of at least about 90° C. and at a pressure of at least about 7 Mpa.

9. The apparatus of claim 7, wherein:
the base has a plurality of parallel grooves formed therein; and
the fins are planar fins, each of the fins being closely received in one of the grooves.

10. A heat sink apparatus, comprising:
an aluminum base; and
a plurality of graphite fins attached to the base, each of the graphite fins being formed of at least one sheet of compressed particles of exfoliated graphite and extending from the base, the sheet material having axes of relatively high thermal conductivity greater than that of aluminum in the plane of the sheet and having a relatively low thermal conductivity across a thickness of the sheet material, the graphite sheet material having a specific gravity no greater than that of aluminum, so that the heat sink apparatus has a thermal performance greater than that of a similar sized all aluminum heat sink while having a weight no greater than that of the all aluminum heat sink.

11. The apparatus of claim 10, wherein the graphite fins are constructed of resin impregnated graphite sheets pressure cured at temperature of at least about 90° C. and at a pressure of at least about 7 Mpa.

12. The apparatus of claim 10, wherein:
the base has a plurality of parallel grooves formed therein; and
the fins are planar fins, each of the fins being closely received in one of the grooves.
